(19) United States
(12) Patent Application Publication
(10) Pub. No.: US 2003/0025132 A1
(43) Pub. Date: Feb. 6, 2003

(54) Inputs and outputs for embedded field programmable gate array cores in application specific integrated circuits

(76) Inventor: John D. Tobey, San Jose, CA (US)

Correspondence Address: GARY T. AKA, 12930 SARATOGA AVENUE, SUITE D1, SARATOGA, CA, 95070, US

(21) Appl. No.: 10/202,443

(22) Filed: Jul. 24, 2002

Related U.S. Application Data
(60) Provisional application No. 60/307,479, filed on Jul. 24, 2001.

(51) Int. Cl. H01L 21/82; H01L 27/10

(52) U.S. Cl. 257/202; 257/203; 438/128; 438/129; 257/208

(57) ABSTRACT

An architecture to efficiently handle primary input and output signals for an embedded FPGA core in an ASIC is disclosed. Only the FPGA core is used without wire-bonding pads and pad ring found in conventional embedded FPGAs. The input and outputs of the embedded FPGA core can be made peripherally or at selected locations throughout the core to obtain high I/O-to-logic ratios and flexibility in I/O placement with high routability.

### CROSS-REFERENCES TO RELATED APPLICATIONS

This patent application claims priority from U.S. Provisional Patent Application No. 60/307,479, filed Jul. 24, 2001, and which is incorporated herein for all purposes.

### BACKGROUND OF THE INVENTION

The present invention is related to configurable interconnection networks in integrated circuits and, in particular, to the FPGA (Field Programmable Gate Array) cores which are embedded in integrated circuits to provide configurable interconnections between defined elements of the integrated circuit.

FPGAs are integrated circuits whose functionalities are designated by the users of the FPGA. The user programs the FPGA (hence the term, “field programmable”) to perform the functions desired by the user. The FPGA has an interconnection network between the logic cells or blocks and the interconnection network and the logic cells are configurable to perform the application desired by the user. Typically, one or more FPGAs are connected with other integrated circuits into an electronic system. The FPGA can be configured to provide the desired signal paths between the other integrated circuits and to condition the signals if required. For FPGAs based on SRAM (Static Random Access Memory) cells to hold the configuration bits, the configuration of the FPGA can be changed by the user for multiple applications of the electronic system.

With shrinking geometries in semiconductor technology, an emerging use for FPGAs is to provide configurable interconnections for defined elements or circuit blocks in ASICs (Application Specific Integrated Circuits). Such elements may include a processor, memory, and peripheral elements in the so-called System-on-a-Chip (SOC), or multi-processor elements of a parallel computing integrated circuit, for example. In some cases, the defined element is obtained from another party as the “Intellectual Property” or IP of the party. The FPGA connects the various defined elements of the ASIC.

Heretofore, the practice has been to simply insert the FPGA with the other defined elements into the integrated circuit. However, this practice is not efficient and wasteful of valuable semiconductor substrate space even with smaller geometries.

The present invention addresses this problem and offers an effective way of embedding an FPGA core with its configurable interconnect network into an integrated circuit.

### SUMMARY OF THE INVENTION

The present invention provides for an integrated circuit having a plurality of defined elements, such as processor units, memory units and special peripheral units, and an FPGA core directly interconnecting the plurality of defined elements. The direct connections may at the periphery of said embedded FPGA core, at points internal to the core, or at both general locations.

### BRIEF DESCRIPTION OF THE DRAWINGS

FIG. 1 illustrates the organization of a discrete FPGA;

FIG. 2A shows the organization of a cell unit which constitutes FPGA core; FIG. 2B is a block diagram of a typical logic core cell in an FPGA core;

FIG. 3A shows the general organization of an exemplary ASIC with an embedded FPGA core according to the present invention; FIG. 3B is a block diagram of an embedded FPGA logic core cell with I/O terminals internal to the FPGA core, according to one embodiment of the present invention; and

FIG. 4 illustrates a routing of internal I/O terminals to the periphery of the embedded FPGA core, according to another embodiment of the present invention.

### DESCRIPTION OF THE SPECIFIC EMBODIMENTS

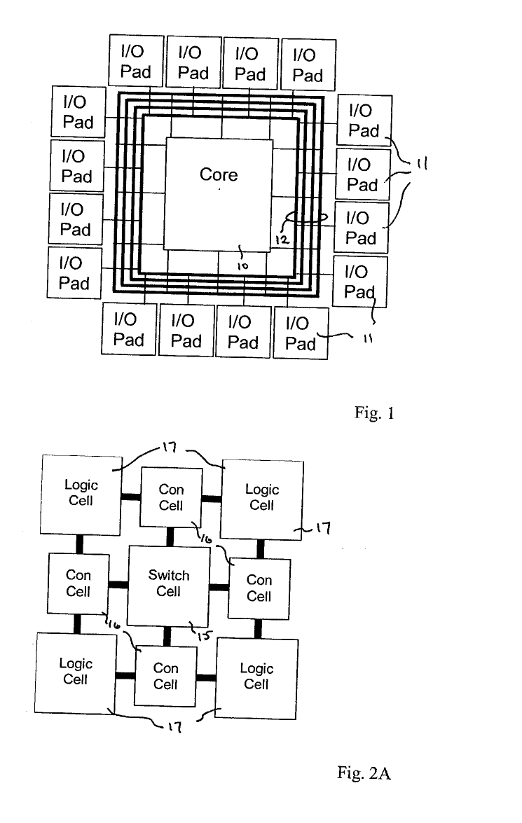

FIG. 1 illustrates the general organization of an FPGA. The FPGA core 10 is placed in the central area of the chip and the input/output pads 11 are placed around the periphery of the chip. The pads 11 are connected to the core 10 with various interconnect structures, typically of rings of routing wires, collectively termed a ring 12, between the pads 11 and the core 10 with programmable connections between the ring 12 and each pad 11, as well as between the ring 12 and the core 10. Alternatively, instead of the concentric rings, the wires may be segmented into separate buses. This organization follows that general layout of other integrated circuits where, in place of an FPGA core, some core functional logic particular to that integrated circuit is set.

The I/O ring architecture allow the pads 11 to be wire-bonded to external pins of a protective package enclosing the integrated circuit by automatic bonding machines during the manufacture of the chip. Typically, the bonding area of the pads is relatively large to accommodate the requirements of this bonding process. The relative size of the pads results in a shortage of the number of pads available for the FPGA core and the core functional logic on the chip. Designs are frequently pad limited.

Another problem for FPGAs in particular is that the I/O ring 12 usually has a limited number of connections. Because any programmability in the ring 12 requires space on the integrated circuit substrate surface for switching devices and configuration memory, designers typically trade off routing flexibility for silicon area. For example, each pad 11 may connect to a subset of the wires in the ring 12, or each wire in the ring 12 may only connect to the core 10 at certain locations. These connection limitations can result in designs which are unroutable, i.e., the configuration desired by the user is not possible.

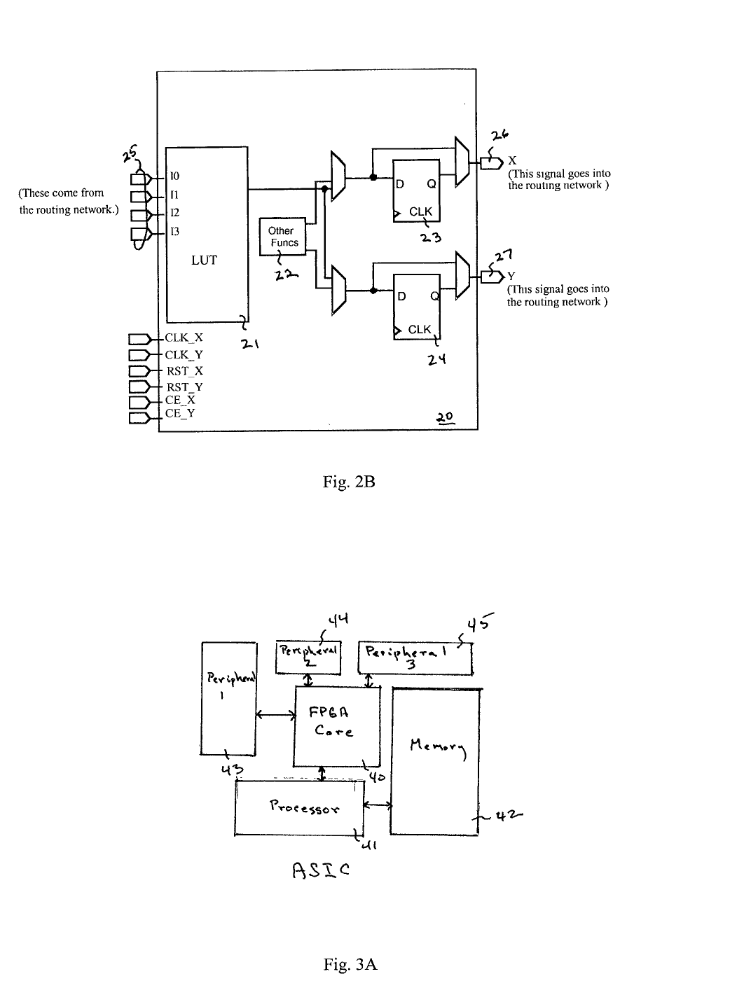

An example of an FPGA core is illustrated by a cell unit in FIG. 2A. This basic array structure unit is repeated in two directions across an integrated circuit to form a mesh architecture of the FPGA core which can be of varying sizes. In this arrayed structure, connections are made between a switch cell 15 and its four neighboring connection cells 16 to the north, east, west, and south directions. The switch cells 15, connection cells 16, and all their wires (i.e., conducting lines of the integrated circuit) and connections constitute the interconnect network for the logic core cells 17, which are formed with programmable logic and latching functions. The logic core cells 17 are used to implement the actual circuit logic, the connection cells 16 are configured to connect the logic core cells 17 to the interconnect network, and the switch cells 15 are configured to implement the desired interconnect network. The flexibility of this traditional architecture lies within the connection cells 16 and the switch cells 15. To make the connections between conducting wires in these cells 15 and 16, there are programmable switches which are responsive to configuration bits which are stored in memory cells.

A typical FPGA logic core cell is shown in FIG. 2B: The logic core cell 20 as an LUT (Look Up Table) 21, the programmable logic element that implements most of the FPGA combinatorial logic. In some cases, a logic block 22 is created for other functions to support more efficient logic implementation. Programmable flip-flops 23 and 24 are present to latch the signals of the core cell 20. Input terminals 25 provide paths into the core cell 20 from the interconnect network provided by the switch cells 15 and connection cells 16 and output terminals 26 and 27 provide paths from the cell 20 to the interconnect network. There are many possible variations of this basic core cell architecture, but a salient feature is the collocation of programmable logic elements (e.g., the LUT 21) and programmable storage elements (e.g., the flip-flops 23 and 24) with a programmable means to interconnect them (the multiplexers in FIG. 2).

In the conventional practice of ASIC design with embedded FPGAs, the entire FPGA is placed into the ASIC and the ASIC defined elements are connected to the embedded FPGA through its pads. The embedded FPGA is then programmed as in the case of the discrete FPGA to the desired connections between the defined elements to serve the targeted application of the ASIC.

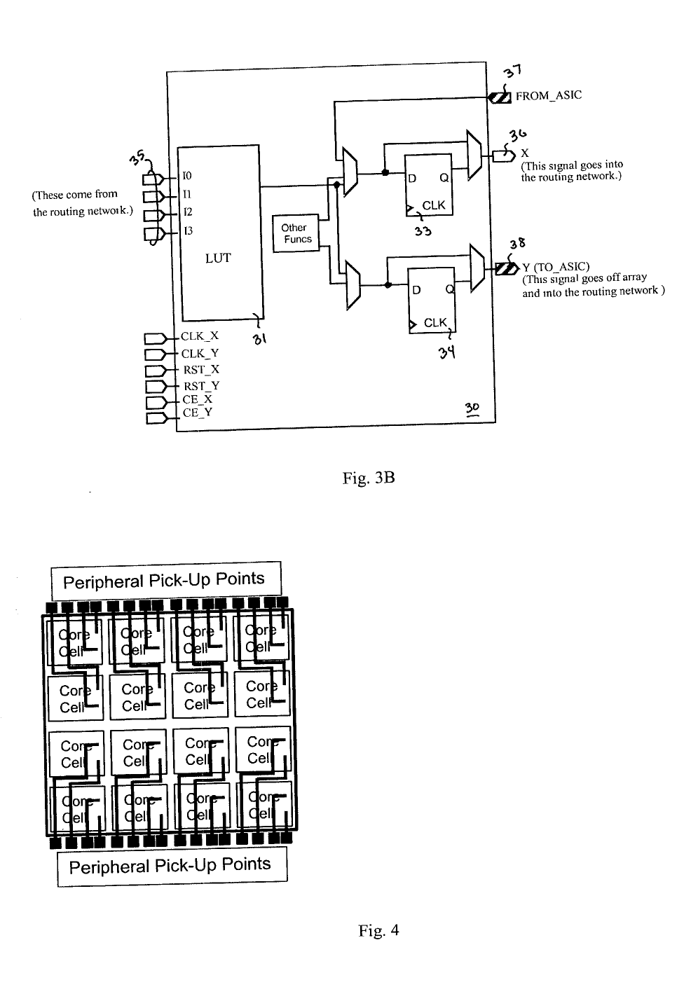

On the other hand, the present invention provides for direct paths into and out of an embedded FPGA core with the defined elements of an ASIC. In the present invention, the pads and the pad ring of the conventional FPGA are stripped away and only the FPGA core is embedded. This is illustrated by FIG. 3A illustrating an exemplary ASIC with an embedded FPGA core 40. The ASIC has a processor 41 with an attached memory 42. Three peripheral units 43-45 selected for the application of the ASIC are interconnected to the FPGA core 40 which can condition the data traveling among the processor 41 and peripheral units 43-45 responsive to the core's configuration bits. The embedded core 40 can reconfigure its interconnect network and modify the operations of its logic core cells.

An embedded FPGA core does not have any bonding pad constraints. Any primary input or output signal can simply be routed like any other wire on the chip, using minimal metal wire spacing between signals. Without any external packaging constraints, the I/O-to-core ratio can be made extremely high. In addition, without an I/O ring, the I/O interconnect can be merged into the core interconnect with negligible overhead and more robust routability can be supported. The programmable storage elements of an FPGA logic core cells may be used to implement the primary inputs and outputs of the given design into the FPGA core. This requires the addition of a programmable means to configure the storage elements as primary I/O's as shown by a modified logic core cell 30 in FIG. 3B. The cell 30 has an additional input terminal 37 which is directly connected to an ASIC defined element. Likewise, instead of being connected to the FPGA core interconnection network, one of the output terminals 38 is connected directly to an ASIC defined element.

Furthermore, the primary I/O's for the embedded FPGA core may be distributed within the core itself, instead of around the core. It is possible to simply define internal pick-up points for these primary I/O connections to the FPGA core and let the ASIC designer route to these points. But for a more compact layout, it is generally preferable for the core to route the wires to pick-up points at the periphery of the FPGA core. There are many possible schemes for routing to the periphery. One simple example is shown below in FIG. 4. Note that the spacing of the peripheral pick-up points is only limited by the metal wire spacing, not by the storage elements or their programming elements required for the conventional I/O ring. Furthermore, any routing from primary inputs or to primary outputs of the embedded FPGA core can use the full interconnect network of the core array, not just a limited I/O ring. There is very little overhead for the I/O support since the I/O configuration bits and peripheral wires can generally be absorbed into the existing core cells of the embedded FPGA core. Finally, there is a general improvement in ASIC performance since the processor, memory, and peripheral elements, the typical defined elements of a SOC ASIC, or the multiple processors, the defined elements of a parallel computing ASIC, for example, are now directly interconnected with the embedded FPGA core without an intervening I/O ring and pads.

The FPGA core without its pads and pad ring is readily adaptable to emerging packaging technologies, such as the so-called “Flip-Chip” bonding technique in which a pattern of contact points is mounted over the substrate surface of an integrated circuit. The contact points, much smaller than a conventional wire bonding pad, contact predetermined locations of the integrated circuit and provide external leads for the integrated circuit. The predetermined locations are spread over the integrated circuit and not only at the periphery of the circuit. Hence flip-chip packaging provides a discrete FPGA without the space-consuming pads and pad ring; only the FPGA core is used.

While the foregoing is a complete description of the embodiments of the invention, it should be evident that various modifications, alternatives and equivalents may be made and used. Accordingly, the above description should not be taken as limiting the scope of the invention which is defined by the metes and bounds of the appended claims.

What is claimed is:

1. An integrated circuit comprising
a plurality of defined elements; and
an FPGA core directly interconnecting said plurality of defined elements.

2. The integrated circuit of claim 1 wherein said plurality of defined elements are directly connected to said FPGA core at the periphery of said core.

3. The integrated circuit of claim 2 wherein said plurality of defined elements are further directly connected to said FPGA core at points internal to said core.

4. The integrated circuit of claim 3 wherein said points internal to said core are connected to wiring leading to terminals at the periphery of said core.

5. The integrated circuit of claim 1 wherein said plurality of defined elements are further directly connected to said FPGA core at points internal to said core.

6. The integrated circuit of claim 5 wherein said points internal to said core are connected to wiring leading to terminals at the periphery of said core.

7. The integrated circuit of claim 1 wherein said defined elements comprise an elements selected from the group having processors, memories and peripheral units.
